(19) United States
(12) Patent Application Publication
(10) Pub. No.: US 2015/0349801 A1
(43) Pub. Date: Dec. 3, 2015

(54) METHOD AND APPARATUS FOR DECODING NON-BINARY LOW DENSITY PARITY CHECK CODE IN COMMUNICATION SYSTEM

(71) Applicant: Samsung Electronics Co., Ltd., Suwon-si (KR)

(72) Inventors: Woo-Myoung PARK, Suwon-si (KR); Kyeong-Cheol YANG, Pohang-si (KR); Sang-Min KIM, Uiwang-si (KR); Min SAGONG, Suwon-si (KR); Seok-Ki AHN, Suwon-si (KR); Chi-Woo LIM, Suwon-si (KR); Sung-Nam HONG, Anyang-si (KR)

(21) Appl. No.: 14/725,679

(22) Filed: May 29, 2015

(30) Foreign Application Priority Data
May 29, 2014 (KR) 10-2014-0065286

(51) Int. Cl. H03M 13/11

(52) U.S. Cl. CPC H03M 13/1131; H03M 13/1171

(57) ABSTRACT

A method for decoding a non-binary Low Density Parity Check (LDPC) code by a decoding apparatus in a communication system is provided. The method includes selecting a predetermined number of symbol messages from among received symbol messages, performing a variable node update process on the selected symbol messages to generate variable node updated symbol messages, performing a check node update process on the variable node updated symbol messages, and performing a decoding operation based on the result of the variable node update process and the check node update process, wherein the performing of the check node update process includes generating an intermediate message for the variable node updated symbol messages using symbol messages which are selected based on reliability, and generating an output message of each edge between a variable node and a check node.

### CROSS-REFERENCE TO RELATED APPLICATION(S)

This application claims the benefit under 35 U.S.C. §119(a) of a Korean patent application filed on May 29, 2014 in the Korean Intellectual Property Office and assigned Serial No. 10-2014-0065286, the entire disclosure of which is hereby incorporated by reference.

### TECHNICAL FIELD

The present disclosure relates to a method and apparatus for decoding a Low Density Parity Check (LDPC) code in a communication system. More particularly, the present disclosure relates to a method and apparatus for decoding a non-binary LDPC code in a communication system.

### BACKGROUND

To meet the demand for wireless data traffic, which has increased since deployment of 4^{th}-Generation (4G) communication systems, efforts have been made to develop an improved 5^{th}-Generation (5G) or pre-5G communication system. Therefore, the 5G or pre-5G communication system is also called a ‘Beyond 4G Network’ or a ‘Post Long-Term Evolution (LTE) System’.

It is considered that the 5G communication system will be implemented in millimeter Wave (mmWave) bands, e.g., 60 GHz bands, so as to accomplish higher data rates. To reduce propagation loss of radio waves and increase a transmission distance, a beam forming technique, a massive multiple-input multiple-output (MIMO) technique, a Full Dimensional MIMO (FD-MIMO) technique, an array antenna technique, an analog beam forming technique, and a large scale antenna technique are discussed in 5G communication systems.

In addition, in 5G communication systems, development for system network improvement is under way based on advanced small cells, cloud Radio Access Networks (RANs), ultra-dense networks, a device-to-device (D2D) communication, a wireless backhaul, a moving network, a cooperative communication, Coordinated Multi-Points (CoMP), reception-end interference cancellation, and the like.

In the 5G system, a Hybrid Frequency Shift Keying (FSK) and Quadrature Amplitude Modulation (QAM) Modulation (FQAM) and a Sliding Window Superposition Coding (SWSC) as an Advanced Coding Modulation (ACM) scheme, and a Filter Bank Multi Carrier (FBMC) scheme, a Non-Orthogonal Multiple Access (NOMA) scheme, and a Sparse Code Multiple Access (SCMA) scheme as an advanced access technology have been developed.

In a communication system, a Low Density Parity Check (LDPC) code has been introduced as one of linear block codes by Gallager in the 1960's. However, further research for the LDPC code has not been conducted for a long time due to the complexity of its implementation.

A turbo code, which was discovered by Berrou, Glavieux, and Thitimajshima, has a performance which is similar to a Shannon's channel capacity. Thus, many analyses for a performance and a characteristic of the turbo code have been conducted, and research for channel coding, which is based on an iterative decoding and a graph, has been in progress. Further, additional research for the LDPC code has been performed, and it has been discovered that the LDPC code has a performance which is similar to a Shannon's channel capacity in a case that the iterative decoding for the LDPC code is performed.

The appearance of the turbo code and the LDPC code, which use the iterative decoding, makes it possible to achieve a performance which is very similar to a Shannon's channel capacity as a theoretical limit of a channel capacity. Also, the turbo code and the LDPC code are used in various communication fields such as a mobile communication, a broadcast, and the like.

The LDPC code may be regarded as a communication network in which each vertex transmits/receives predetermined messages through each edge in a case that information on encoded bits is mapped to a vertex within a Tanner graph, and relations among the encoded bits are mapped to edges within the Tanner graph, so an inherent decoding algorithm may be derived from this. That is, the LDPC code is generally defined using a parity check matrix, and may be expressed using a bipartite graph which is referred to as the Tanner graph. In the Tanner graph, vertices included in the Tanner graph may be classified into two types of nodes, i.e., a variable node and a check node, and the LDPC code is expressed with a bipartite graph including variable nodes and check nodes. The variable node is mapped to an encoded bit one-to-one.

The turbo code and the LDPC code may be classified into a scheme of using a binary code and a scheme of using a non-binary code. The binary code has an excellent performance in a case that a length of a frame which is supported in a communication system in which the binary code is used is longer than a threshold length. However, a performance of the binary code is reduced in a case that the length of the frame is shorter than the threshold length, or the communication system in which the binary code is used uses a modulation scheme which has a modulation order higher than a preset threshold modulation order. So, in a case that a communication system supports a frame which has a relatively short length or a modulation order which has a relatively high modulation order, a non-binary turbo code or a non-binary LDPC code has a relatively excellent performance compared to a binary turbo code or a binary LDPC code.

For example, if a communication system supporting a Single-Input Single-Output (SISO) scheme uses a non-binary code and a 256 QAM scheme is used, up to 1 dB better performance is acquired as compared to a case in which the communication system uses a binary code. For another example, if a communication system supporting a Single User Multiple Input Multiple Output (SU-MIMO) scheme uses a non-binary code, about 1˜3 dB better performance is acquired according to antenna configuration and a modulation scheme as compared to a case in which the communication system uses a binary code.

Meanwhile, if a non-binary code is used, a complexity of a decoder may increase compared to a case that a binary code is used. More concretely, if a non-binary turbo code is used, a decoder has a very high complexity in proportion to a field order of a symbol and K+1 square of the total number of symbol Log-Likelihood Ratio (LLR) messages “q”. Here, K denotes a constraint length. The symbol LLR messages denote elements included in a symbol LLR vector.

Further, a decoding algorithm for a non-binary LDPC code, which is generated by directly expanding a decoding algorithm for a binary LDPC code as a non-binary form, has a complexity in proportion to the square of the q, so the decoding algorithm for the non-binary LDPC code has a relatively low complexity as compared to a decoding algorithm for a non-binary turbo code.

However, if the q becomes larger, a complexity of the decoding algorithm for the non-binary LDPC code also becomes higher. Thus, research for decreasing the complexity of the decoding algorithm for the non-binary LDPC code is in progress.

A typical example of a decoding algorithm for the non-binary LDPC code according to the related art may include a log BP algorithm, a scaled min-sum (MS) algorithm, a normalized MS algorithm, an Extended MS (EMS) algorithm, an Improved EMS (I-EMS) algorithm, and the like.

In the log BP algorithm, complex operations such as multiplication, look-up table processing, and the like are included in a check node update process. Here, an algorithm in which the check node update process is simplified with a minimum and summation operation is the scaled MS algorithm or the normalized MS algorithm. Upon decoding a non-binary LDPC code, the normalized MS algorithm uses a symbol LLR vector of size q, so the normalized MS algorithm has a very high complexity. Here, the q denotes the total number of symbol LLR messages.

Thus, decoding algorithms for selecting a predetermined number of dominant elements among elements included in a symbol LLR vector, i.e., symbol LLR messages, and using the selected dominant elements have been developed. Here, typical examples of a decoding algorithm include the EMS algorithm and the I-EMS algorithm. The I-EMS algorithm is implemented by decreasing a complexity of the EMS algorithm.

Further, an I-EMS with Bubble Check (I-EMS with BC) algorithm, in which a calculation complexity of a check node update process is reduced by enhancing the I-EMS algorithm, has been developed. The I-EMS with BC algorithm has been known as an algorithm that has the lowest complexity among all decoding algorithms for a non-binary LDPC code which have been developed up to now.

As described above, even though various decoding algorithms for a non-binary LDPC code have been proposed, the various decoding algorithms for the non-binary LDPC code still have a high complexity. So, there is a need for decreasing a complexity of a decoding algorithm for a non-binary LDPC code.

The above information is presented as background information only to assist with an understanding of the present disclosure. No determination has been made, and no assertion is made, as to whether any of the above might be applicable as prior art with regard to the present disclosure.

### SUMMARY

Aspects of the present disclosure are to address at least the above-mentioned problems and/or disadvantages and to provide at least the advantages described below. Accordingly, an aspect of the present disclosure is to provide a method and apparatus for decoding a non-binary Low Density Parity Check (LDPC) code in a communication system.

Another aspect of the present disclosure is to provide a method and apparatus for decoding a non-binary LDPC code, thereby decreasing the calculation complexity in a communication system.

Another aspect of the present disclosure is to provide a method and apparatus for decoding a non-binary LDPC code, thereby decreasing the decoding delay in a communication system.

In accordance with an aspect of the present disclosure, a method for decoding a non-binary LDPC code by a decoding apparatus in a communication system is provided. The method includes selecting a predetermined number of symbol messages from among received symbol messages, performing a variable node update process on the selected symbol messages to generate variable node updated symbol messages, performing a check node update process on the variable node updated symbol messages, and performing a decoding operation based on the result of the variable node update process and the check node update process, wherein the performing of the check node update process includes generating an intermediate message for the variable node updated symbol messages using symbol messages which are selected based on reliability, and generating an output message of each edge between a variable node and a check node.

In accordance with another aspect of the present disclosure, an apparatus for decoding a non-binary LDPC code in a communication system is provided. The apparatus includes a processor configured to perform an operation of selecting a predetermined number of symbol messages from among received symbol messages, and performing a variable node update process on the selected symbol messages to generate variable node updated symbol messages, an operation of performing a check node update process on the variable node updated symbol messages, and an operation of performing a decoding operation based on the result of the variable node update process and the check node update process, wherein the operation of performing the check node update process includes an operation of generating an intermediate message for the variable node updated symbol messages using symbol messages which are selected based on reliability, and generating an output message of each edge between a variable node and a check node.

Other aspects, advantages, and salient features of the disclosure will become apparent to those skilled in the art from the following detailed description, which, taken in conjunction with the annexed drawings, discloses various embodiments of the present disclosure.

### BRIEF DESCRIPTION OF THE DRAWINGS

The above and other aspects, features, and advantages of certain embodiments of the present disclosure will be more apparent from the following description taken in conjunction with the accompanying drawings, in which:

FIG. 1 schematically illustrates an inner structure of a decoding apparatus for decoding a non-binary Low Density Parity Check (LDPC) code using an Improved Extended MS (I-EMS) algorithm in a communication system according to the related art;

FIG. 2 schematically illustrates an inner structure of a decoding apparatus for decoding a non-binary LDPC code in a communication system according to an embodiment of the present disclosure;

FIG. 3 schematically illustrates a process of decoding a non-binary LDPC code in a decoding apparatus in a communication system according to an embodiment of the present disclosure;

FIG. 4 schematically illustrates a first domain conversion process included in a check node update process in a communication system according to an embodiment of the present disclosure;

FIGS. 5A, 5B, and 5C schematically illustrate a process of calculating an intermediate message and an output message in a check node update process in a communication system according to various embodiments of the present disclosure;

FIG. 6 schematically illustrates a process of updating an intermediate message in a check node update process in a communication system according to an embodiment of the present disclosure;

FIG. 7 schematically illustrates a process of generating an output message for each edge in a check node update process in a communication system according to an embodiment of the present disclosure;

FIG. 8 schematically illustrates a second domain conversion process in a check node update process in a communication system according to an embodiment of the present disclosure;

FIG. 9 schematically illustrates an example of a performance of a decoding algorithm for a non-binary LDPC code in a communication system according to an embodiment of the present disclosure; and

FIG. 10 schematically illustrates another example of a performance of a decoding algorithm for a non-binary LDPC code in a communication system according to an embodiment of the present disclosure.

Throughout the drawings, it should be noted that like reference numbers are used to depict the same or similar elements, features, and structures.

### DETAILED DESCRIPTION

The following description with reference to the accompanying drawings is provided to assist in a comprehensive understanding of various embodiments of the present disclosure as defined by the claims and their equivalents. It includes various specific details to assist in that understanding but these are to be regarded as merely exemplary. Accordingly, those of ordinary skill in the art will recognize that various changes and modifications of the various embodiments described herein can be made without departing from the scope and spirit of the present disclosure. In addition, descriptions of well-known functions and constructions may be omitted for clarity and conciseness.

The terms and words used in the following description and claims are not limited to the bibliographical meanings, but, are merely used by the inventor to enable a clear and consistent understanding of the present disclosure. Accordingly, it should be apparent to those skilled in the art that the following description of various embodiments of the present disclosure is provided for illustration purpose only and not for the purpose of limiting the present disclosure as defined by the appended claims and their equivalents.

It is to be understood that the singular forms “a,” “an,” and “the” include plural referents unless the context clearly dictates otherwise. Thus, for example, reference to “a component surface” includes reference to one or more of such surfaces.

Although ordinal numbers such as “first,” “second,” and so forth will be used to describe various components, those components are not limited herein. The terms are used only for distinguishing one component from another component. For example, a first component may be referred to as a second component and likewise, a second component may also be referred to as a first component, without departing from the teaching of the inventive concept. The term “and/or” used herein includes any and all combinations of one or more of the associated listed items.

The terminology used herein is for the purpose of describing various embodiments of the present disclosure only and is not intended to be limiting. It will be further understood that the terms “comprises” and/or “has,” when used in this specification, specify the presence of a stated feature, number, step, operation, component, element, or combination thereof, but do not preclude the presence or addition of one or more other features, numbers, steps, operations, components, elements, or combinations thereof.

The terms used herein, including technical and scientific terms, have the same meanings as terms that are generally understood by those skilled in the art, as long as the terms are not differently defined. It should be understood that terms defined in a generally-used dictionary have meanings coinciding with those of terms in the related technology.

According to various embodiments of the present disclosure, an electronic device may include communication functionality. For example, an electronic device may be a smart phone, a tablet personal computer (PC), a mobile phone, a video phone, an e-book reader, a desktop PC, a laptop PC, a netbook PC, a personal digital assistant (PDA), a portable multimedia player (PMP), an mp3 player, a mobile medical device, a camera, a wearable device (e.g., a head-mounted device (HMD), electronic clothes, electronic braces, an electronic necklace, an electronic appcessory, an electronic tattoo, or a smart watch), and/or the like.

According to various embodiments of the present disclosure, an electronic device may be a smart home appliance with communication functionality. A smart home appliance may be, for example, a television (TV), a digital versatile disc (DVD) player, an audio, a refrigerator, an air conditioner, a vacuum cleaner, an oven, a microwave oven, a washer, a dryer, an air purifier, a set-top box, a TV box (e.g., Samsung HomeSync™, Apple TV™, or Google TV™), a gaming console, an electronic dictionary, an electronic key, a camcorder, an electronic picture frame, and/or the like.

According to various embodiments of the present disclosure, an electronic device may be a medical device (e.g., magnetic resonance angiography (MRA) device, a magnetic resonance imaging (MRI) device, computed tomography (CT) device, an imaging device, or an ultrasonic device), a navigation device, a global positioning system (GPS) receiver, an event data recorder (EDR), a flight data recorder (FDR), an automotive infotainment device, a naval electronic device (e.g., naval navigation device, gyroscope, or compass), an avionic electronic device, a security device, an industrial or consumer robot, and/or the like.

According to various embodiments of the present disclosure, an electronic device may be furniture, part of a building/structure, an electronic board, electronic signature receiving device, a projector, various measuring devices (e.g., water, electricity, gas or electro-magnetic wave measuring devices), and/or the like that include communication functionality.

According to various embodiments of the present disclosure, an electronic device may be any combination of the foregoing devices. In addition, it will be apparent to one having ordinary skill in the art that an electronic device according to various embodiments of the present disclosure is not limited to the foregoing devices.

According to various embodiments of the present disclosure, for example, a decoding apparatus for decoding a Low Density Parity Check (LDPC) code may be implemented in a portable terminal such as a User Equipment (UE), and the portable terminal may be an electronic device.

An embodiment of the present disclosure proposes a method and apparatus for decoding a non-binary LDPC code in a communication system.

An embodiment of the present disclosure proposes a method and apparatus for decoding a non-binary LDPC code, thereby decreasing the calculation complexity in a communication system.

An embodiment of the present disclosure proposes a method and apparatus for decoding a non-binary LDPC code, thereby decreasing the decoding delay in a communication system.

A method and apparatus proposed in various embodiments of the present disclosure may be applied to various mobile communication systems such as a Long Term Evolution (LTE) mobile communication system, an LTE-Advanced (LTE-A) mobile communication system, a Licensed-Assisted Access (LAA) mobile communication system, a High Speed Downlink Packet Access (HSDPA) mobile communication system, a High Speed Uplink Packet Access (HSUPA) mobile communication system, a High Rate Packet Data (HRPD) mobile communication system proposed in a 3^{rd} Generation Project Partnership 2 (3GPP2), a Wideband Code Division Multiple Access (WCDMA) mobile communication system proposed in the 3GPP2, a CDMA mobile communication system proposed in the 3GPP2, an Institute of Electrical and Electronics Engineers (IEEE) 802.16m communication system, an IEEE 802.16e communication system, an Evolved Packet System (EPS), a Mobile Internet Protocol (Mobile IP) system, and/or the like.

Firstly, an operation complexity of a decoding algorithm for a non-binary LDPC code according to the related art will be described below.

In decoding algorithms for a non-binary LDPC code according to the related art, e.g., a log BP algorithm, a scaled min-sum (MS) algorithm, a normalized MS algorithm, an Extended MS (EMS) algorithm, an Improved EMS (I-EMS) algorithm, and the like, calculation for a message output from a check node is performed in a scheme of detecting a value of a combination of which reliability is the highest among all combinations of all elements included in messages input from a variable node to the check node. For convenience, a message input from a variable node to a check node will be referred to as a Variable to Check (V2C) message. A typical example of the scheme of detecting the value of the combination of which the reliability is the highest includes a Forward/Backward Recursion (F/B Recursion) scheme.

In an I-EMS algorithm, total operations which are necessary for computing a Check to Variable (C2V) message of a check node using the F/B Recursion scheme may be performed with low calculation complexity. Here, a C2V message denotes a message input from a check node to a variable node. In the I-EMS algorithm, a decoding apparatus selects a predetermined number of symbol Log-Likelihood Ratio (LLR) messages among q symbol LLR messages (vectors), and performs a decoding operation using the selected symbol LLR messages. Thus, a tradeoff between a decoding performance and complexity may be appropriately adjusted. In the F/B Recursion scheme, a decoding apparatus performs the next calculation using a previous calculation value of symbol LLR messages. Thus, the decoding delay inevitably occurs. Further, the calculation complexity of the I-EMS algorithm is still higher than the calculation complexity of a binary LDPC decoding algorithm.

A decoding process of an I-EMS algorithm which uses an F/B Recursion scheme in a communication system according to the related art will be described below.

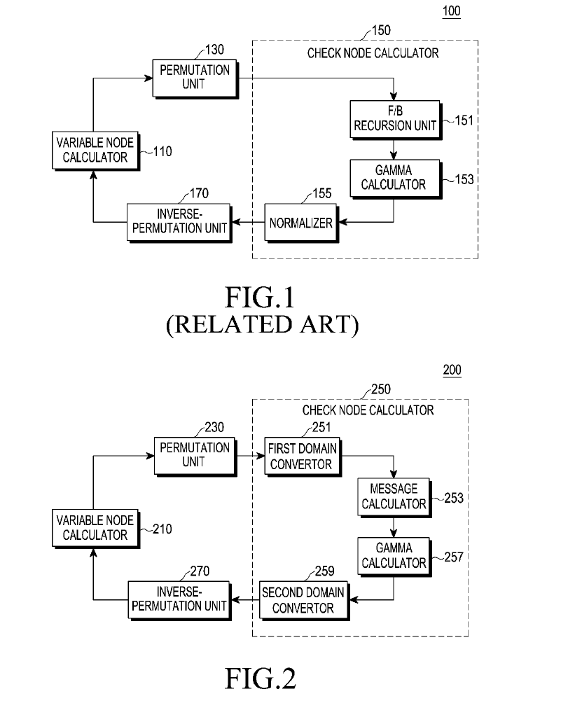

An inner structure of a decoding apparatus for decoding a non-binary LDPC code using an I-EMS algorithm in a communication system according to the related art will be described with reference to FIG. 1.

FIG. 1 schematically illustrates an inner structure of a decoding apparatus for decoding a non-binary LDPC code using an I-EMS algorithm in a communication system according to the related art.

Referring to FIG. 1, a decoding apparatus 100 includes a variable node calculator 110, a permutation unit 130, a check node calculator 150, and an inverse-permutation unit 170. The check node calculator 150 includes an F/B Recursion unit 151, a gamma calculator 153, and a normalizer 155.

A sorter (not shown in FIG. 1) selects a predetermined number of symbol LLR messages among symbol LLR messages of each symbol which is received in a de-modulator (not shown in FIG. 1) through a channel in an order of value larger. The variable node calculator 110 performs a variable node update process of calculating a V2C message using a remaining C2V message(s) except for a C2V message which is received from a check node to which the V2C message will be transferred. Each of the C2V message and the V2C message is a symbol LLR message. The permutation unit 130 performs a permutation operation on a symbol index of a symbol LLR message(s) which is transferred from the variable node calculator 110 to the check node calculator 150, i.e., a V2C message(s) based on a value of an element of which a value is not zero among elements included in a parity check matrix used in an LDPC code. That is, the permutation unit 130 performs a permutation operation on the V2C message based on the parity check matrix.

The check node calculator 150 performs a check node update process of calculating the C2V message using a remaining V2C message(s) except for a V2C message which is received from a variable node to which the C2V message will be transferred.

In the check node update process, the F/B Recursion unit 151 selects a predetermined number of symbol LLR messages among symbol LLR messages of a V2C message which is received from a variable node in an order of reliability, and performs a check node processing based on the selected symbol LLR messages.

In the check node update process, the gamma calculator 153 calculates a gamma value by adding a predetermined offset value to a maximum symbol LLR message value among symbol LLR message values of the symbol LLR messages for each edge. Here, an edge denotes a connection between a check node and a variable node which are mapped to each element of which a value is not zero among elements included in a parity check matrix.

The normalizer 155 outputs the C2V message as a normalized value in order to prevent an overflow in hardware implementation. The inverse-permutation unit 170 performs an inverse-permutation operation on a symbol index of a symbol LLR message which is transferred from the check node calculator 150 to the variable node calculator 110, i.e., a C2V message. The inverse-permutation unit 170 performs the inverse-permutation on the C2V message based on a parity check matrix.

The decoding apparatus in FIG. 1 has a large decoding delay since the F/B Recursion unit 151 included in the check node calculator 150 uses the F/B Recursion scheme. Here, the higher a code rate of an LDPC code becomes, the larger the complexity and the decoding delay of a related decoding apparatus becomes.

Upon calculating a value of a C2V message, a check node calculator to which a non-binary LDPC decoding algorithm of the related art is applied calculates values of all combinations of remaining messages except for a V2C message which is received from a related edge, orders the calculated values in an order of value larger, i.e., in an order of reliability higher, and selects a predetermined number of values among the ordered values. This C2V message calculating scheme causes an increase of the calculation complexity and the decoding delay.

Thus, an embodiment of the present disclosure proposes a scheme of effectively calculating a C2V message in a check node calculator in order to reduce the calculation complexity and the decoding delay in a decoding apparatus for decoding a non-binary LDPC code.

An inner structure of a decoding apparatus for decoding a non-binary LDPC code in a communication system according to an embodiment of the present disclosure will be described with reference to FIG. 2.

FIG. 2 schematically illustrates an inner structure of a decoding apparatus for decoding a non-binary LDPC code in a communication system according to an embodiment of the present disclosure.

Referring to FIG. 2, a decoding apparatus 200 includes a variable node calculator 210, a permutation unit 230, a check node calculator 250, and an inverse-permutation unit 270. The check node calculator 250 includes a first domain convertor 251, a message calculator 253, a gamma calculator 257, and a second domain convertor 259.

A sorter (not shown in FIG. 2) selects a predetermined number of symbol LLR messages among symbol LLR messages of each symbol which is received in a de-modulator (not shown in FIG. 2) through a channel in an order of value larger. The variable node calculator 210 performs a variable node update process of calculating a V2C message using a remaining C2V message(s) except for a C2V message which is received from a check node to which the V2C message will be transferred. Each of the C2V message and the V2C message is a symbol LLR message. The permutation unit 230 performs a permutation operation on a symbol index of a symbol LLR message(s) which is transferred from the variable node calculator 210 to the check node calculator 250, i.e., a V2C message(s) based on a value of an element of which a value is not zero among elements included in a parity check matrix used in an LDPC code. That is, the permutation unit 230 performs a permutation operation on the V2C message based on the parity check matrix.

The check node calculator 250 performs a check node update process of calculating a C2V message using a remaining V2C message(s) except for a V2C message which is received from a variable node to which the C2V message will be transferred.

The check node calculator 250 calculates a C2V message using a V2C message(s) which is transferred from at least one variable node which is adjacent to a check node which the check node calculator 250 intends to calculate the C2V message as an output message. That is, the check node calculator 250 performs a check node update process of calculating the C2V message using a remaining message(s) except for a V2C message which is received from a variable node to which the C2V message will be transferred. Further, a check node update scheme according to an embodiment of the present disclosure may improve a scheme used in a check node calculator included in a decoding apparatus of the related art, e.g., a check node calculator 150 in FIG. 1 to reduce the calculation complexity and the decoding delay.

The check node update process performed in the check node calculator 250 according to an embodiment of the present disclosure may include a stage 1, a stage 2, a stage 3, and a stage 4.

### Stage 1) a First Domain Conversion Stage

Stage 1 includes a stage 1-1 and a stage 1-2, and the stage 1-1 and the stage 1-2 will be described below.

Stage 1-1) The check node calculator 250 performs a hard decision on each V2C message, i.e., each symbol LLR message at a symbol LLR vector of each edge which is transferred from the variable node calculator 210 to detect a Maximum Likelihood (ML) symbol. The check node calculator 250 stores a symbol index of the ML symbol and a symbol LLR message value of the symbol LLR message.

Stage 1-2) The check node calculator 250 performs a permutation operation on each of symbol indices of remaining elements except for an element of the ML symbol among elements included in a symbol LLR vector of each edge and each of symbol LLR message values of symbol LLR messages into a difference between each of the symbol indices of the remaining elements and the symbol index of the ML symbol which is detected in the stage 1-1 and a difference between each of the values of the symbol LLR messages and the symbol LLR message value of the symbol LLR message which is detected in the stage 1-1. It will be understood that the stage 1-2 is a stage of generating a delta domain message.

### Stage 2) a Stage of Calculating an Intermediate Message and an Output Message for Each Edge

Stage 2 includes a stage 2-1, a stage 2-2, and a stage 2-3, and the stage 2-1, the stage 2-2, and the stage 2-3 will be described below.

Stage 2-1) The check node calculator 250 selects a predetermined number of symbol LLR messages among elements included in an ordered symbol LLR vector which is input to a check node, i.e., symbol LLR messages in an order of value smaller thereby a symbol index is not duplicated, and generates symbol LLR vectors which are newly ordered based on the selected symbol LLR messages.

Stage 2-2) The check node calculator 250 selects a predetermined number of symbol LLR messages among symbol LLR messages which are not included in a symbol LLR vector which is input to each edge among the symbol LLR vectors generated in the stage 2-1 in an order of value smaller for each edge, and generates an intermediate message based on the selected symbol LLR messages.

Stage 2-3) If necessary, the check node calculator 250 selects the smallest element, i.e., a symbol LLR message except for a 0 symbol, i.e., an ML symbol among elements included in the intermediate message to add a symbol LLR message value of the selected symbol LLR message to values of all remaining elements. If there is no element which has a symbol index equal to the result value which is generated by adding the symbol LLR message value of the selected symbol LLR message to the values of all remaining elements and has a smaller symbol LLR message value among elements included in a current intermediate message, and the result value is less than a maximum value among values of previous elements, that is, the result value has a high reliability, the check node calculator 250 updates an intermediate message into the value which has the high reliability, i.e., a new value. The check node calculator 250 may optionally perform the operation of the stage 2-3. The check node calculator 250 calculates output messages for each edge based on a symbol index and location information of each element included in a final intermediate message which is generated according to the described stages.

### Stage 3) a Gamma (γ) Calculation Stage

The check node calculator 250 uses a value which is generated by adding and a predetermined offset to a value of an output message which has a maximum value among output messages for each edge as a gamma value of each output message.

### Stage 4) a Second Domain Conversion Stage

The check node calculator 250 generates C2V messages which will be transferred to a variable node by converting a domain of the output messages which are acquired in the stage 3 from the delta domain according to the first domain conversion process into an original domain before the delta domain conversion. In this time, a symbol index of each of the C2V messages is updated, and values of remaining elements except for a 0 symbol, i.e., an ML symbol are converted into negative values.

Referring to FIG. 2, the first domain convertor 251 performs the delta domain process in the stage 1 in the check node update process. The message calculator 253 calculates the intermediate message and the output message of each edge in the stage 2. The gamma calculator 257 performs a gamma calculation process in the stage 3. The second domain convertor 259 generates C2V messages which will be transferred to a variable node by converting a domain of the delta messages which are acquired in the stage 3 into the original domain before the delta domain conversion according to the stage 4, i.e., the second domain conversion stage, and outputs the generated C2V messages.

While the variable node calculator 210, the permutation unit 230, the check node calculator 250, and the inverse-permutation unit 270 are described as separate units, it is to be understood that this is merely for convenience of description. In other words, two or more of the variable node calculator 210, the permutation unit 230, the check node calculator 250, and the inverse-permutation unit 270 may be incorporated into a single unit. The decoding apparatus 200 may be implemented as one processor.

While the first domain convertor 251, the message calculator 253, the gamma calculator 257, and the second domain convertor 259 are described as separate units, it is to be understood that this is merely for convenience of description. In other words, two or more of the first domain convertor 251, the message calculator 253, the gamma calculator 257, and the second domain convertor 259 may be incorporated into a single unit. The check node calculator 250 may be implemented as one processor.

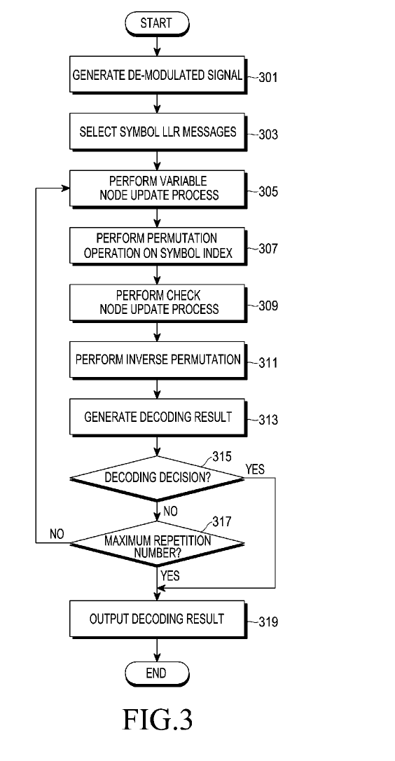

An inner structure of a decoding apparatus for decoding a non-binary LDPC code in a communication system according to an embodiment of the present disclosure has been described with reference to FIG. 2, and a process of decoding a non-binary LDPC code in a decoding apparatus in a communication system according to an embodiment of the present disclosure will be described with reference to FIG. 3.

FIG. 3 schematically illustrates a process of decoding a non-binary LDPC code in a decoding apparatus in a communication system according to an embodiment of the present disclosure.

Referring to FIG. 3, a de-modulator performs a de-modulation operation on a signal which is received through a channel to generate a signal which is de-modulated as a symbol LLR form at operation 301. A sorter selects a predetermined number of symbol LLR messages among symbol LLR messages as elements included in each of symbol LLR vectors in an order of value larger at operation 303.

A variable node calculator (e.g., variable node calculator 210 included in a decoding apparatus 200) performs a variable node update process at operation 305. The variable node calculator performs the variable node update process of calculating a V2C message using a remaining C2V message(s) except for a C2V message which is received from a check node to which the V2C message will be transferred.

A permutation unit (e.g., permutation unit 230 included in the decoding apparatus 200) performs a permutation operation on a symbol index of a symbol LLR message(s) which is transferred from the variable node calculator to a check node calculator, i.e., a V2C message(s) corresponding to a parity check matrix at operation 307. The check node calculator (e.g., check node calculator 250 included in the decoding apparatus 200) performs a check node update process from a stage 1 to a stage 4 which includes a first domain conversion process, calculation of an intermediate message and an output message of each edge, calculation of a gamma, and a second domain conversion process at operation 309.

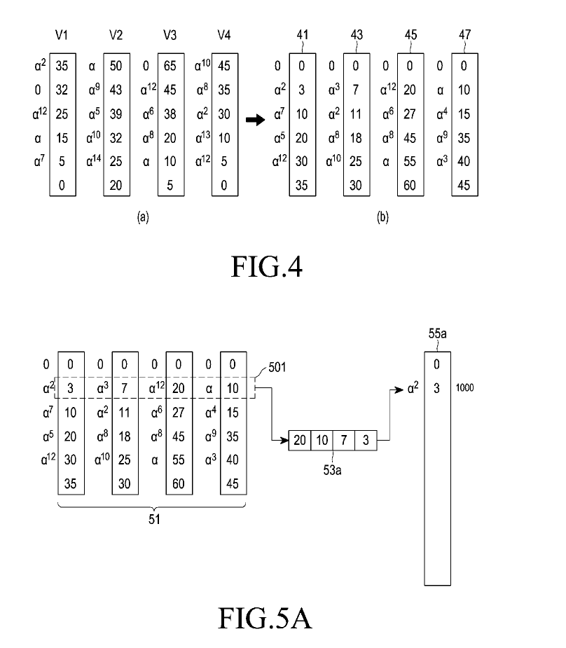

A check node update process in a communication system according to an embodiment of the present disclosure will be described with reference to FIGS. 4 to 8.

Firstly, a first domain conversion process included in a check node update process in a communication system according to an embodiment of the present disclosure will be described with reference to FIG. 4.

FIG. 4 schematically illustrates a first domain conversion process included in a check node update process in a communication system according to an embodiment of the present disclosure.

Referring to FIG. 4, (a) indicates an example of selecting a predetermined number of symbol LLR messages among symbol LLR messages of each edge, i.e., an edge 1, an edge 2, an edge 3, and an edge 4 in an order of a value larger, i.e., in an order of reliability higher. A set of the symbol LLR messages of each of the edge 1, the edge 2, the edge 3, and the edge 4 is included in a symbol LLR vector of a related edge. For example, as described in (a), a set of symbol LLR messages 35, 32, 25, 15, 5, and 0 is included in a symbol LLR vector of a related edge, i.e., the edge V1. Related symbol indices α², 0, α¹², α, and α⁷ are described in the left side of the symbol LLR messages 35, 32, 25, 15, and 5.

A first domain convertor converts each of symbol indices of remaining elements except for an element of an ML symbol among elements included in a symbol LLR vector of each edge and each of symbol LLR values of symbol LLR messages as described in (a) into a difference between each of the symbol indices of the remaining elements and the symbol index of the ML symbol and a difference between each of the symbol LLR values of the symbol LLR messages and the symbol LLR value of the symbol LLR message of the ML symbol as described in (b). For example, the elements 35, 32, 25, 15, 5, and 0 included in the symbol LLR vector of the edge V1 are converted into (35−35=0, 35−32=3, 35−25=10, 35−15=20, 35−5=30, 35−0=35) based on first domain conversion like a reference sign 41. The symbol indices of the elements included in the symbol LLR vector of the edge V1 are converted into (α²−α²=0, α²−0=α², α²−α¹²=α⁷, α²−α=α⁵, α²−α⁷=α¹²) through the first domain conversion for the elements included in the symbol LLR vector of the edge V1. An operation rule on a Galois Field (GF) described in Table 1 is applied to an operation for conversion of the symbol indices, and the operation in Table 1 is an operation in a case that a GF(16), and a primitive polynomial: f(x)=x⁴+x+1, α⁴+α+1=0 are assumed.

Thus, the result of the first domain conversion for the elements included in the symbol LLR vector of each of the edge V2, the edge V3, and the edge V4 is described as reference signs 43, 45, and 47.

TABLE 1

| Multiplicative Representation | Additive Representation |
|---|---|
| 0 | 0 |
| 1 | 1 |
| α | α |
| α² | α² |
| α³ | α³ |
| α⁴ | α + 1 |
| α⁵ | α² + α |
| α⁶ | α³ + α² |
| α⁷ | α³ + α + 1 |
| α⁸ | α² + 1 |
| α⁹ | α³ + α |
| α¹⁰ | α² + α + 1 |
| α¹¹ | α³ + α² + α |
| α¹² | α³ + α² + α + 1 |
| α¹³ | α³ + α² + 1 |
| α¹⁴ | α³ + 1 |

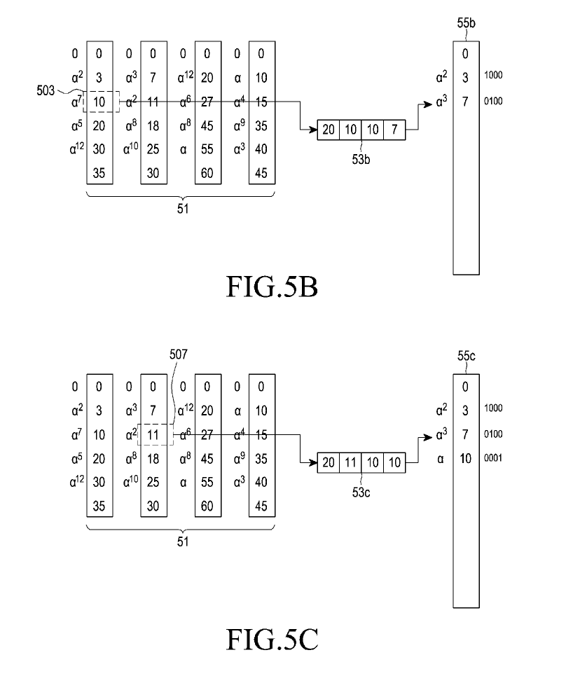

A first domain conversion process included in a check node update process in a communication system according to an embodiment of the present disclosure has been described with reference to FIG. 4, and a process of calculating an intermediate message and an output message in a check node update process in a communication system according to an embodiment of the present disclosure will be described with reference to FIGS. 5A to 5C.

FIGS. 5A to 5C schematically illustrate a process of calculating an intermediate message and an output message in a check node update process in a communication system according to various embodiments of the present disclosure.

Referring to FIG. 5A, a message calculator selects a predetermined number of symbol LLR messages 3, 7, 10, and 20 in an order of a value smaller from among symbol LLR vectors 51 which are ordered according to first domain conversion as described in (b) in FIG. 4 thereby related symbol indices are not duplicated at operation 501. The message calculator generates a symbol LLR vector 53a which is newly ordered based on the selected symbol LLR messages 3, 7, 10, and 20.

The message calculator firstly locates a 0 symbol, i.e., an ML symbol like a reference sign 55a, and selects a symbol LLR message from the symbol LLR vector 53a in an order of a value smaller to detect the first element 3 among elements included in an intermediate message. Here, α² which is illustrated in the left side of the first element 3 indicates a symbol index, and 1000 which is illustrated in the right side of the first element 3 is location information indicating an edge to which the first element 3 belongs. The 1000 indicates that the first element 3 belongs to the first edge V1 among the four edges V1 to V4.

Referring to FIG. 5B, a scheme of detecting the second element 7 among the elements included in the intermediate message in a message calculator will be described below.

The message calculator selects a symbol LLR message 10 in an order of value smaller from among the symbol LLR vectors 51 thereby related symbol indices are not duplicated in order to calculate the second element 7 at operation 503. The message calculator generates a symbol LLR vector 53b including the selected symbol LLR messages 7, 10, 10, 20.

The message calculator selects a symbol LLR message from the symbol LLR vector 53b in an order of value smaller to detect the second element 7 from the symbol LLR vector 53b like a reference sign 55b. A symbol index of the second element 7 is α³, and location information of the second element 7 is 0100.

Referring to FIG. 5C, a scheme of detecting the third element 10 among the elements included in the intermediate message in a message calculator will be described below.

The message calculator selects a symbol LLR message 11 in an order of value smaller from among the symbol LLR vectors 51 thereby related symbol indices are not duplicated in order to calculate the third element 10 at operation 507. The message calculator generates a symbol LLR vector 53c including the selected symbol LLR messages 10, 10, 11, 20.

The message calculator selects a symbol LLR message from the symbol LLR vector 53c in an order of value smaller to detect the third element 10 from the symbol LLR vector 53c like a reference sign 55c. A symbol index of the third element 10 is a, and location information of the second element 7 is 0001.

In an embodiment of the present disclosure, an intermediate message is proposed to reduce the calculation complexity for a check node update process. The number of elements included in the intermediate message may be equal to or greater than the number of elements included in a symbol LLR vector which is selected for decoding in the first domain conversion process. For example, it is possible that the number of elements included in an intermediate message is selected as a multiple of the number of elements included in a symbol LLR vector.

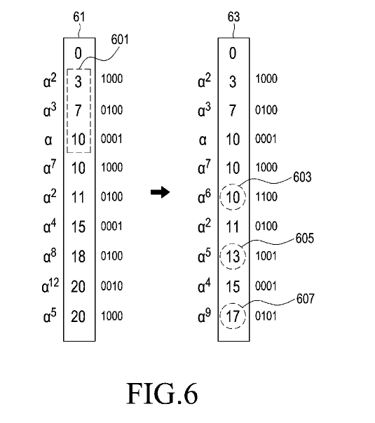

A process of updating an intermediate message in a check node update process in a communication system according to an embodiment of the present disclosure will be described with reference to FIG. 6.

FIG. 6 schematically illustrates a process of updating an intermediate message in a check node update process in a communication system according to an embodiment of the present disclosure.

Referring to FIG. 6, a reference sign 61 indicates an example of an intermediate message which is generated according to a process of calculating an intermediate message and an output message in a check node update process in a communication system according to an embodiment of the present disclosure as described in FIGS. 5A to 5C.

If there is no element which has a symbol index equal to a result value and has a smaller symbol LLR message value among elements included in an intermediate message 61, and result values (3+7=10, 3+10=13, 7+10=17) 603, 605, and 607, which are less than a maximum value 20 among values of previous elements are detected, a message calculator updates an intermediate message thereby the result values are included in the intermediate message as new elements like a reference sign 63.

Symbol indices and location information of the new elements are detected by adding symbol indices of other elements which are added for the intermediate message update and adding location information of the other elements, respectively.

A process of updating an intermediate message in FIG. 6 is for increasing reliability of elements included in the intermediate message, and the process of updating the intermediate message may be optionally performed.

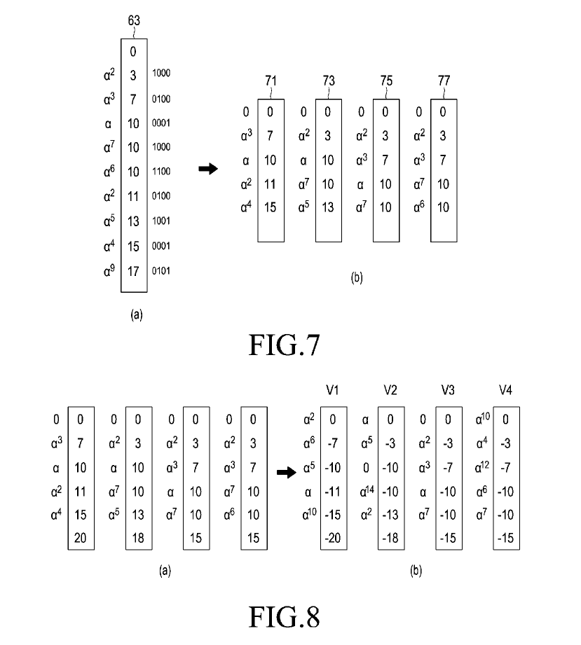

A process of updating an intermediate message in a check node update process in a communication system according to an embodiment of the present disclosure has been described with reference to FIG. 6, and a process of generating an output message for each edge in a check node update process in a communication system according to an embodiment of the present disclosure will be described with reference to FIG. 7.

FIG. 7 schematically illustrates a process of generating an output message for each edge in a check node update process in a communication system according to an embodiment of the present disclosure.

Referring to FIG. 7, (a) indicates an example of an intermediate message 63 which is finally generated according to a process of updating an intermediate message in a communication system according to an embodiment of the present disclosure as described in FIG. 6.

A message calculator generates an output message 71, 73, 75, and 77 for each edge using the generated intermediate message like (b). An operation of generating the output message 71, 73, 75, and 77 for each edge will be described below.

The message calculator detects output messages for each edge based on symbol indices and location information of elements included in the intermediate message. For example, a symbol index and location information of the first element 3 included in the intermediate message are α² and 1000, respectively, so the message calculator locates the first element 3 in output messages 73, 75, and 77 of the second edge to the fourth edge one by one, except for the first edge which corresponds to 1 in the location information. A symbol index and location information of the second element 7 included in the intermediate message are α³ and 0100, respectively, so the message calculator locates the second element 7 in output messages 71, 75, and 77 of the first edge, the third edge, and the fourth edge one by one, except for the second edge which corresponds to 1 in the location information. In this way, the message calculator locates remaining elements included in the intermediate message in output messages of related edges.

A process of generating an output message for each edge in a check node update process in a communication system according to an embodiment of the present disclosure has been described with reference to FIG. 7, and the second domain conversion process in a check node update process in a communication system according to an embodiment of the present disclosure will be described with reference to FIG. 8.

FIG. 8 schematically illustrates a second domain conversion process in a check node update process in a communication system according to an embodiment of the present disclosure.

Referring to FIG. 8, (a) indicates a result of adding an offset 5 according to gamma calculation to each of the last elements 15, 13, 10, and 10 included in output messages for edges in a check node update process in a communication system according to an embodiment of the present disclosure as described in FIG. 7.

A second domain convertor converts a domain of the output message for each edge that the offset is applied into an original domain, that is, the second domain convertor converts a symbol index of the output message for each edge that the offset is applied into an original symbol index to generate C2V messages which will be transferred to a variable node as illustrated in (b) in FIG. 8. At this time, element values of remaining elements except for a 0 symbol, i.e., an ML symbol are converted into negative values.

Referring again to FIG. 3, an inverse-permutation unit performs an inverse permutation operation on a symbol index of a symbol LLR message(s), i.e., a C2V message(s) which will be transferred from a check node calculator to a variable node calculator based on a parity check matrix at operation 311. The decoding apparatus performs a hard decision operation by adding a symbol LLR message value of a symbol LLR message which is transferred from a variable node to a check node and a symbol LLR message value of a symbol LLR message which is received from a channel, and generates a decoding result based on the hard decision operation at operation 313.

The decoding apparatus determines whether a product of a vector value according to the decoding result and a parity check matrix is 0 at operation 315. That is, the decoding apparatus determines whether a decoding decision is made.

If the product of the vector value according to the decoding result and the parity check matrix is not 0, that is, the decoding decision is not made, the decoding apparatus determines whether a repetition decoding number is equal to a maximum repetition decoding number at operation 317. If the repetition decoding number is not equal to the maximum repetition decoding number, the decoding apparatus returns to operation 305.

If the repetition decoding number is equal to the maximum repetition decoding number, the decoding apparatus proceeds to operation 319. If the product of the vector value according to the decoding result and the parity check matrix is 0, the decoding apparatus proceeds to operation 319. The decoding apparatus outputs a decoding result at operation 319.

Although FIG. 3 illustrates a process of decoding a non-binary LDPC code in a decoding apparatus in a communication system according to an embodiment of the present disclosure, various changes could be made to FIG. 3. For example, although shown as a series of operations, various operations in FIG. 3 could overlap, occur in parallel, occur in a different order, or occur multiple times.

As described in FIGS. 2 to 8, an apparatus for decoding a non-binary LDPC code in a communication system according to an embodiment of the present disclosure may include a variable node calculator, a check node calculator, and a decoder (not shown in FIGS. 2 to 8).

The variable node calculator performs a variable node update process on a predetermined number of symbol messages among symbol messages which are received from a channel. The check node calculator performs a check node update process on the variable node updated symbol messages. The decoder performs a decoding operation based on the result of the variable node update process and the check node update process.

The check node calculator selects symbol messages among the variable node updated symbol messages in an order of reliability higher, generates an intermediate message using the selected symbol messages, and generates an output message for each edge between a variable node and a check node using the intermediate message.

In an embodiment of the present disclosure, it will be assumed that a length of a V2C message is equal to a length of a C2V message. However, the length of the V2C message may be different from the length of the C2V message. For example, the length of the C2V message may be longer than the length of the V2C message for a performance increase. Alternatively, a decoding apparatus may order elements included in a remaining V2C message(s) except for a V2C message which is input to each edge to calculate an output message for each of the elements.

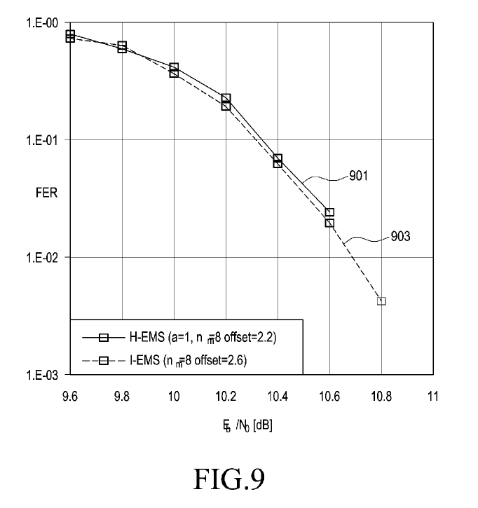

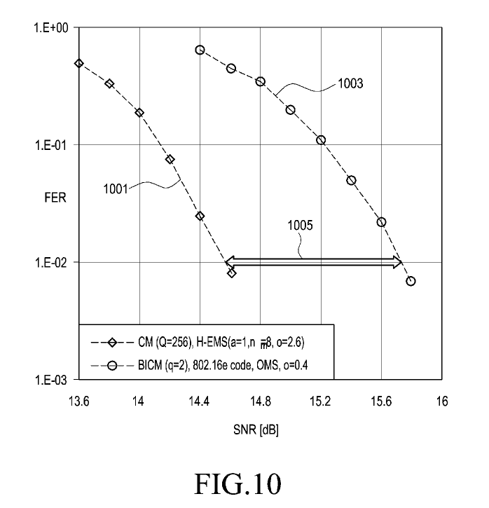

A performance of a decoding algorithm for a non-binary LDPC code in a communication system according to an embodiment of the present disclosure will be described with reference to FIGS. 9 and 10.

An example of a performance of a decoding algorithm for a non-binary LDPC code in a communication system according to an embodiment of the present disclosure will be described with reference to FIG. 9.

FIG. 9 schematically illustrates an example of a performance of a decoding algorithm for a non-binary LDPC code in a communication system according to an embodiment of the present disclosure.

Referring to FIG. 9, a reference sign 901 indicates a performance in a case that a decoding algorithm according to an embodiment of the present disclosure is applied, and a reference sign 903 indicates a performance in a case that an I-EMS with Bubble Check (I-EMS with BC) algorithm is applied.

It will be noted that performance graphs illustrated in FIG. 9 are performance graphs in a case that a Single Input Single Output (SISO) scheme is used, a 256 Quadrature Amplitude Modulation (QAM) scheme is used, and an Additive White Gaussian Noise (AWGN) is considered.

As described in FIG. 9, a decoding algorithm according to an embodiment of the present disclosure has a performance which is very similar to a performance of the I-EMS with BC algorithm. Further, the calculation complexity and the decoding delay of the decoding algorithm according to an embodiment of the present disclosure are reduced by about 48.9% and 60.2%, respectively, compared to the I-EMS with BC algorithm.

An example of a performance of a decoding algorithm for a non-binary LDPC code in a communication system according to an embodiment of the present disclosure has been described with reference to FIG. 9, and another example of a performance of a decoding algorithm for a non-binary LDPC code in a communication system according to an embodiment of the present disclosure will be described with reference to FIG. 10.

FIG. 10 schematically illustrates another example of a performance of a decoding algorithm for a non-binary LDPC code in a communication system according to an embodiment of the present disclosure.

Referring to FIG. 10, a reference sign 1001 indicates a performance in a case that a decoding algorithm according to an embodiment of the present disclosure is applied, and a reference sign 1003 indicates a performance in a case that a binary LDPC code used in an IEEE802.16e communication system of the related art is applied.

It will be noted that performance graphs illustrated in FIG. 10 are performance graphs in a case that a Single User-Multiple Input Multiple Output (SU-MIMO) scheme is used, a 16 QAM scheme is used, and a Rayleigh environment is considered.

As described in FIG. 10, if the number of elements included in a selected symbol LLR vector nₘ is 8 (nₘ=8), a decoding algorithm according to an embodiment of the present disclosure has a better performance of about 1.2 dB compared to a binary LDPC decoding algorithm (1005). Further, the calculation complexity of the decoding algorithm according to an embodiment of the present disclosure is reduced about 2.6 times compared to an I-EMS with BC algorithm.

So, it will be understood that the calculation complexity and the decoding delay of a decoding algorithm for a non-binary LDPC code according to an embodiment of the present disclosure are reduced compared to decoding algorithms for a non-binary LDPC code according to the related art.

In a decoding algorithm for a non-binary LDPC code according to an embodiment of the present disclosure, a check node update process may calculate an output message without using an F/B Recursion scheme. So, in a decoding algorithm for a non-binary LDPC code according to an embodiment of the present disclosure, the decoding delay is reduced.

In a decoding algorithm for a non-binary LDPC code according to an embodiment of the present disclosure, it is possible to use ordering information of a message which is transferred from a check node to a variable node, so the calculation complexity may be reduced.

As is apparent from the foregoing description, an embodiment of the present disclosure enables to decode a non-binary LDPC code in a communication system.

An embodiment of the present disclosure enables to decode a non-binary LDPC code thereby decreasing the calculation complexity in a communication system.

An embodiment of the present disclosure enables decoding of a non-binary LDPC code thereby decreasing the decoding delay in a communication system.

Certain aspects of the present disclosure may also be embodied as computer readable code on a non-transitory computer readable recording medium. A non-transitory computer readable recording medium is any data storage device that can store data, which can be thereafter read by a computer system. Examples of the non-transitory computer readable recording medium include read only memory (ROM), random access memory (RAM), compact disc ROMs (CD-ROMs), magnetic tapes, floppy disks, optical data storage devices, and carrier waves (such as data transmission through the Internet). The non-transitory computer readable recording medium can also be distributed over network coupled computer systems so that the computer readable code is stored and executed in a distributed fashion. In addition, functional programs, code, and code segments for accomplishing the present disclosure can be easily construed by programmers skilled in the art to which the present disclosure pertains.

It can be appreciated that a method and apparatus according to an embodiment of the present disclosure may be implemented by hardware, software and/or a combination thereof. The software may be stored in a non-volatile storage, for example, an erasable or re-writable ROM, a memory, for example, a RAM, a memory chip, a memory device, or a memory integrated circuit (IC), or an optically or magnetically recordable non-transitory machine-readable (e.g., computer-readable), storage medium (e.g., a CD, a DVD, a magnetic disk, a magnetic tape, and/or the like). A method and apparatus according to an embodiment of the present disclosure may be implemented by a computer or a mobile terminal that includes a controller and a memory, and the memory may be an example of a non-transitory machine-readable (e.g., computer-readable), storage medium suitable to store a program or programs including instructions for implementing various embodiments of the present disclosure.

The present disclosure may include a program including code for implementing the apparatus and method as defined by the appended claims, and a non-transitory machine-readable (e.g., computer-readable), storage medium storing the program. The program may be electronically transferred via any media, such as communication signals, which are transmitted through wired and/or wireless connections, and the present disclosure may include their equivalents.

An apparatus according to an embodiment of the present disclosure may receive the program from a program providing device which is connected to the apparatus via a wire or a wireless and store the program. The program providing device may include a memory for storing instructions which instruct to perform a content protect method which has been already installed, information necessary for the content protect method, and the like, a communication unit for performing a wired or a wireless communication with a graphic processing device, and a controller for transmitting a related program to a transmitting/receiving device based on a request of the graphic processing device or automatically transmitting the related program to the transmitting/receiving device.

While the present disclosure has been shown and described with reference to various embodiments thereof, it will be understood by those skilled in the art that various changes in form and details may be made therein without departing from the spirit and scope of the present disclosure as defined by the appended claims and their equivalents.

What is claimed is:

1. A method for decoding a non-binary Low Density Parity Check (LDPC) code by a decoding apparatus in a communication system, the method comprising:
selecting a predetermined number of symbol messages from among received symbol messages;
performing a variable node update process on the selected symbol messages to generate variable node updated symbol messages;
performing a check node update process on the variable node updated symbol messages; and
performing a decoding operation based on the result of the variable node update process and the check node update process,
wherein the performing of the check node update process includes generating an intermediate message for the variable node updated symbol messages using symbol messages which are selected based on reliability, and generating an output message of each edge between a variable node and a check node.

2. The method of claim 1, wherein the performing of the check node update process comprises generating the output message of each edge using a symbol index and location information of each symbol message included in the intermediate message.

3. The method of claim 2, wherein the location information indicates an edge to which each symbol message included in the intermediate message belongs.

4. The method of claim 1, wherein the performing of the check node update process further comprises performing a first domain conversion process of converting a symbol index and a symbol message value of each of remaining elements except for an element of which reliability is the highest among elements included in a symbol vector of each edge into a difference between the symbol index of each of the remaining elements and a symbol index of the element of which the reliability is the highest and a difference between the symbol message value of each of the remaining elements and a symbol message value of the element of which the reliability is the highest for the variable node updated symbol messages.

5. The method of claim 4, wherein the performing of the check node update process further comprises performing a second domain conversion process of converting the output message of each edge into a domain which is before the first domain conversion process is performed.

6. The method of claim 1, further comprising:
if there is a symbol message of which a symbol index is equal to a sum of element values of related elements among elements included in the intermediate message, there is no element which has a symbol message of which a symbol message value is less than a symbol message value of the symbol message, and there is an element of which an element value is less than a maximum value among element values of previous elements, updating the intermediate message thereby the element of which the element value is less than the maximum value is included into the intermediate message as a new element.

7. The method of claim 1, wherein each of the variable node updated symbol messages is a Variable to Check (V2C) message which is transferred from a variable node to a check node, and
wherein each of the check node updated symbol messages is a Check to Variable (C2V) message which is transferred from the check node to the variable node.

8. The method of claim 7, wherein a length of the C2V message is longer than a length of the V2C message.

9. The method of claim 1, wherein a number of symbol messages included in the intermediate message is greater than or equal to a number of symbol messages which are selected in an order of reliability higher.

10. The method of claim 1, wherein the symbol message is a symbol Log-Likelihood Ratio (LLR) message.

11. An apparatus for decoding a non-binary Low Density Parity Check (LDPC) code in a communication system, the apparatus comprising:
a processor configured to perform an operation of selecting a predetermined number of symbol messages from among received symbol messages and performing a variable node update process on the selected symbol messages to generate variable node updated symbol messages, an operation of performing a check node update process on the variable node updated symbol messages, and an operation of performing a decoding operation based on the result of the variable node update process and the check node update process,
wherein the operation of performing the check node update process includes an operation of generating an intermediate message for the variable node updated symbol messages using symbol messages which are selected based on reliability, and generating an output message of each edge between a variable node and a check node.

12. The apparatus of claim 11, wherein the operation of performing the check node update process comprises an operation of generating the output message of each edge using a symbol index and location information of each symbol message included in the intermediate message.

13. The apparatus of claim 12, wherein the location information indicates an edge to which each symbol message included in the intermediate message belongs.

14. The apparatus of claim 11, wherein the operation of performing the check node update process further comprises an operation of performing a first domain conversion process of converting a symbol index and a symbol message value of each of remaining elements except for an element of which reliability is the highest among elements included in a symbol vector of each edge into a difference between the symbol index of each of the remaining elements and a symbol index of the element of which the reliability is the highest and a difference between the symbol message value of each of the remaining elements and a symbol message value of the element of which the reliability is the highest for the variable node updated symbol messages.

15. The apparatus of claim 14, wherein the operation of performing the check node update process further comprises an operation of performing a second domain conversion process of converting the output message of each edge into a domain which is before the first domain conversion process is performed.

16. The apparatus of claim 11, wherein, if there is a symbol message of which a symbol index is equal to a sum of element values of related elements among elements included in the intermediate message, there is no element which has a symbol message of which a symbol message value is less than a symbol message value of the symbol message, and there is an element of which an element value is less than a maximum value among element values of previous elements, the processor updates the intermediate message thereby the element of which the element value is less than the maximum value is included into the intermediate message as a new element.

17. The apparatus of claim 11, wherein each of the variable node updated symbol messages is a Variable to Check (V2C) message which is transferred from a variable node to a check node, and
wherein each of the check node updated symbol messages is a Check to Variable (C2V) message which is transferred from the check node to the variable node.

18. The apparatus of claim 17, wherein a length of the C2V message is longer than a length of the V2C message.

19. The apparatus of claim 11, wherein a number of symbol messages included in the intermediate message is greater than or equal to a number of symbol messages which are selected in an order of reliability higher.

20. The apparatus of claim 11, wherein the symbol message is a symbol Log-Likelihood Ratio (LLR) message.
